(19) United States
(12) Patent Application Publication
(10) Pub. No.: US 2002/0196091 A1
(43) Pub. Date: Dec. 26, 2002

(54) On-chip CMOS oscillator and current reference therefore

(76) Inventor: Markus Niederberger, Schindellegi (CH)

Correspondence Address: U.S. Philips Corporation, 580 White Plains Road, Tarrytown, NY, 10591, US

(21) Appl. No.: 10/056,470

(22) Filed: Jan. 17, 2002

(30) Foreign Application Priority Data
Jan. 19, 2001 (EP) 01200201.0

(51) Int. Cl. H03B 5/26

(52) U.S. Cl. 331/143

(57) ABSTRACT

Integrated oscillator circuit of the relaxation type, wherein the circuit comprises a controllable current source I(β) and a gate oxide capacitor (Cox) which both have a dependency on a common transconductance β.

The present invention relates to a CMOS chip provided with a fully on-chip oscillator, as defined in the preamble of the following claim 1.

CMOS chips without any external components are known. They usually have quite big frequency spread due to process variations for frequencies up to a few hundred kilohertz the on-chip CMOS oscillators are most often produced as relaxation oscillator types. The frequency thereof is determined by a resistor and a capacitor, or by a current and a capacitor. Both, resistors and capacitors usually suffer from a quite big process spread in standard CMOS processes so that the frequency spread of the on-chip relaxation oscillator is even bigger.

The present invention seeks to solve, at least to reduce the spread of frequencies in the objective CMOS chip type in an advantageous, readily implementable manner. According to the invention such is realised by the features defined in the characterizing portion of the present claim 1.

With a circuit according to the invention the dependency of the current source and the capacitor Cox on the common transconductance parameter β will at least to a significant extend if not fully cancel out. Thus a fully on-chip CMOS oscillator with low frequency spread is realised. The invention will now further be explained by way of an example according to a drawing in which:

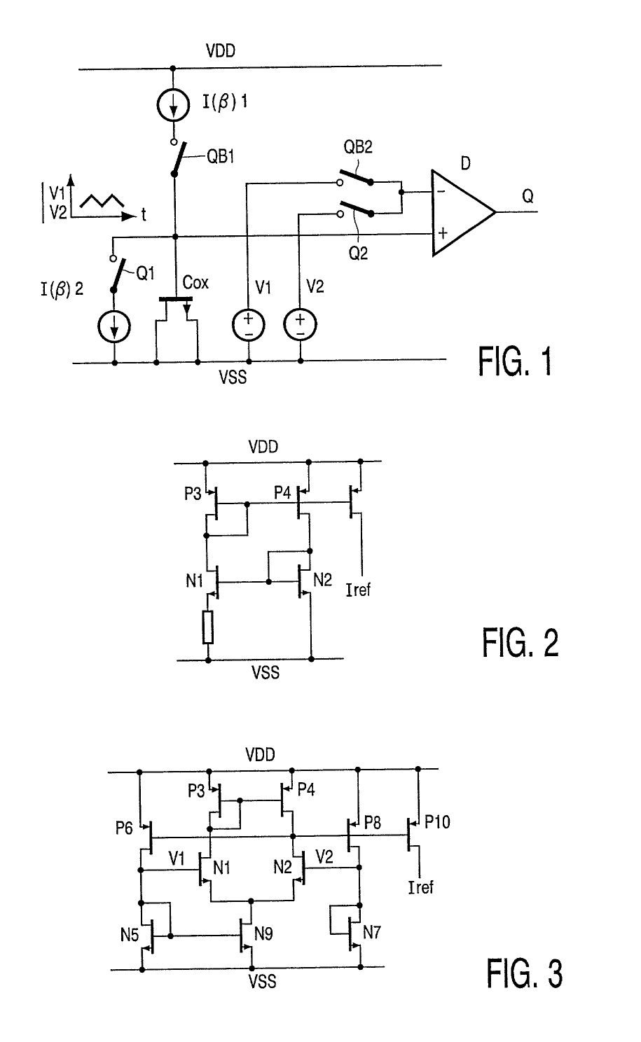

FIG. 1 is a schematic representation of an oscillator circuit according to the invention;

FIG. 2 represents a current source, specifically adapted in accordance with a further aspect of the invention for use in combination with the circuit according to FIG. 1.

In the figures equal references relate to corresponding components.

In FIG. 1 the circuit according to the invention is implemented between voltage lines VDD and VSD. The circuit comprises a current source I(β1) in a line connecting to VDD and on the other hand via a switch means QB1 to a current node. The node further connects to the drain of field effect transistor Cox, to a second current source I(β2) via a switch means Q2 and to the positive connection of a differential amplifier, alternatively denoted operational amplifier. The second transistor K(β)2 connects to the lead VSB, to which also both ends of the main path of transistor Cox connect. Positive voltage sources realised by components, in casu voltage referenced sources V1 and V2 are present in respective leads connecting to lead VSB on the one hand, and via a common connection, to the negative side of the amplifier D, i.e. the inverting input on the other hand. Between the common connection and the components V1 and V2, each lead of V1 and V2 comprises a switch, QB2 and Q2 respectively.

In the circuit of FIG. 1 a current source depending solely on the circuits transconductance parameter β is applied. FIG. 3, in accordance with the invention provides a favourable embodiment for such current source, however also other current sources with the same process dependencies may be applied. In combination, the current Iref, alternatively denoted Idpβ, of the reference current source is given by the following equation:

I_{ref}=V_{T}²·β_{sq}·K_{gcom} (1)

in which

K_{gcom}=geometric factor, which depends only on the geometries of the transistors used in the current reference circuit in FIG. 2

β_{sq}=transconductance parameter of the transistor

V_{T}=thermal voltage, given by the equation V_{T}=n·k·t/q

The transconductance parameter β_{sq} of the circuit can from equation (1) be rewritten as

β_{sq}=μₒ·Cₒₓ (2)

where

μₒ=the mobility of the electron (N-channel) or holes (P-channel) respectively

Cₒₓ=the gate oxide capacitance per area.

From equation (1) and (2) it is, based on the idea underlying the invention, derived that the oscillator frequency of the circuit in FIG. 1 is given by the equation

$$\begin{matrix}{f}_{arc} = \frac{I ( β )}{2 \cdot C \cdot ( {V}_{1} - {V}_{2} )} = \frac{{V}_{T}^{2} \cdot {β}_{s q} \cdot {K}_{g e o m}}{2 \cdot {C}_{o x} \cdot A {C}_{o x} \cdot ( {V}_{1} - {V}_{2} )} & ( 3 ) \\ = \frac{{V}_{T}^{2}}{2} = \frac{{V}_{T}^{2} \cdot μ0 \cdot {K}_{g e o m}}{2 \cdot {A}_{C o x} \cdot ( {V}_{1} - {V}_{2} )} & ( 4 )\end{matrix}$$

in which A_{Cox} is the chip area of the gate oxide capacitor.

The latter equation (4), as derived on the basis of the invention, shows that the mobility coefficient μ₀ is the only process parameter on which the oscillator frequency depends. Advantegeous use is made of the circumstance that in first order approximation, the mobility coefficient μ₀ is constant in CMOS processes.

Simulations of the oscillator according to the invention showed that a ratio of fₘₐₓ/fₘᵢₙ<1,5 is feasible. The oscillator frequency of the oscillator according to the invention depends theoretically only on the accuracy of the two reference voltages V₁ and V₂ Thus these voltages are taken from a bandgap reference so that the frequency spread is quite small.

Further, in first order approximation, the value Cₒₓ is temperature independent. The temperature dependency of the oscillator frequency is therefore the same as for I_{ref}. This leads to the following temperature behaviour of the oscillator frequency.

f_{osc}(T)=f_{osc}(T₀)·(T/T₀)^{0,5 . . . 1} (5)

The temperature dependency of the oscillator frequency is in accordance with a further aspect of the invention further minimized by the reference potentials V₁ and V₂ being produced not constant over the temperature but are slightly temperature dependent to compensate the temperature dependency of f_{osc} in the formula above.

Because Cₒₓ is not constant for low voltages across the capacitor (CV-curve), V₁ and V₂ are choosen such that Cₒₓ operates always in that range where Cₒₓ stays constant.

As to the current source mentioned in the above, the invention in a further aspect thereof also provides for a favourably embodied low voltage current supply, reflected in the diagram of FIG. 3.

Prior art current sources, alternatively denoted current references, with a relatively small power supply rejection and a relatively low minimum supply voltage of 3 V exist. One such prior art current source is reflected in the block diagram of FIG. 2. It is needed in many integrated circuits for providing a bias current for analog circuits. Contemporary applications however require such current sources to provide a reference current which has a small spread over process variation and over all operating conditions of the integrated circuit. Also, especially for low voltage applications, it is necessary that the current reference operates at the low supply voltage. Although the prior art circuits like that of FIG. 2 satisfy such conditions for application, they suffer from the problem that the reference current Iref deducted from such prior art CMOS current references have a relatively high dependency on the supply voltage. The present invention has sought to provide for a non-chip CMOS current source, meeting the above said conditions, however having a relatively low supply voltage dependency of the referenced current Iref, while preferably also having a smaller spread of the referenced current due to process variations within the reference circuit.

According to the present aspect of the invention this is achieved in that the circuit comprises a controllable current source for generating a reference current on the bases of a geometry difference of the transistors (N1, N2) of a differential pair comprised in the circuit (N1-P10). With the current reference circuit according to the invention a high ohmic resistor may be omitted so that also favourably a relatively small chip area is required for the new current reference circuit.

As may be taken from FIG. 3, the principle of the new circuit is relatively simple. The transistors N1, N2, P3 and N9 form a simple differential stage. Considering that the geometries of the transistors N1 and N2 would in principle be equal, and likewise the geometries of P3 and P4, the differential input stage will have a zero input offset voltage. A low supply voltage dependency of Iref is however achieved because the drain source voltages V_{ds} across the transistors N1 and N2 are equal due to the feedback loop of the circuit.

In case the geometries of the transistors are not equal as described above, and N1 and N2 operate in weak inversion than the built in input of said voltage will become non zero. This may be seen from the following equation

$${V}_{off} = {V}_{1} - {V}_{2} = {V}_{T} ln ( \frac{{W}_{1} - {L}_{1} {W}_{2} - {L}_{1}}{{W}_{3} - {L}_{3} {W}_{1} - {L}_{2}} ) \qquad ( 6 )$$

in which:

$${V}_{T} = \frac{n \cdot k \cdot t}{q}$$

represents the thermal voltage which is proportional to the absolute temperature T

Wx width of the transistor

Lx length of the transistor

Due to this built-in-input offset V_{off}, the present circuit is made in equilibrium by an arrangement in which the voltage drop accross transistor N5 is exactly the voltage amount of V_{off} higher than accross transistor N7. This is in accordance with the invention mathematically expressed by the following condition

$${V}_{off} = V1 - V2 = √ 2 ( √ \frac{1}{{β}_{N5}} \cdot {I}_{D p e} - √ \frac{1}{{β}_{N7}} \cdot {I}_{D p e} ) \qquad ( 7 )$$

which solved for the reference current I_{Dpe} leads to

$${I}_{D p s} = \frac{{( {V}_{T} \cdot ln ( \frac{{W}_{3} \cdot {L}_{4}}{{W}_{4} \cdot {L}_{3}} - \frac{{W}_{2} \cdot {L}_{1}}{{W}_{1} \cdot {L}_{2}} ) )}^{2}}{2 \cdot \frac{1}{{β}_{s q}} \cdot ( \sqrt{\frac{{L}_{5} \cdot {W}_{6} \cdot {L}_{8}}{{W}_{5} \cdot {L}_{6} \cdot {W}_{8}} - \sqrt{\frac{{L}_{7}}{{W}_{7}}}} )} = {V}_{T}^{2} \cdot β s q \cdot {K}_{geom} \qquad ( 8 )$$

in this equation K_{geom} depends solarly on the geometries of the transistors. If the geometries of the transistors are much bigger than their minimum size, the only dependencies of reference current I_{Dpb} are the process variation of β_{sq} and the temperature T. It is, in accordance with an idea underlying the invention assumed that the temperature dependency of β_{sq} the same as the temperature dependency of the mobility of the electrons in the transistor N-channel and the holes in the transistor P-channel respectively so that the reference current I_{Dpβ} in accordance with the invention is eventually achieved in a manner expressed by the following equation:

$${I}_{D p b} ( T ) = {I}_{D p b} ( {T}_{0} ) \cdot {( \frac{T}{{T}_{0}} )}^{0 , 5 …1} \qquad ( 9 )$$

in which T is the temperature and T₀ the reference temperature in Kelvin.

It thus shows that the reference current I_{Dpβ} derived from the circuit according to the invention in fact at least virtually only depends on temperature so that a relatively low spread overboad process variation and overall operating conditions of the integrated circuit.

In detail the circuit according to the invention is arranged with a transistor P6 of which the main path on the one hand connects to voltage supply line VDD and on the other hand to the main path of transistor N5, the main path of which on the other hand connects to voltage line VSS. The gate of transistor P6 connects to the gate of transistor P8, the main path of which on the one hand connects to voltage supply line Vdd and on the other hand to the main path of transistor N7, the main path of which on the other hand connects to the voltage path VSS. The gate of both transistors N5 and N7 is connected to the main path between the transistors N5 and P6 and between N7 and P8 respectively. Between the connection of the transistors P6 and P8 with the voltage supply line Vdd, the main path of transistors P3 and P4 are each also connected to the voltage supply line Vdd, while the gates of P3 and P4 are interconnected. This interconnection is lead to the main path of P3 at a location between P3 and transistor N1. The main path of which on the one hand connects to the main path of transistor P3 and on the other hand to the main path of a transistor N2, the main path of which on the other hand is connected to the main path of transistor P4. The gate of transistor N1 is connected to the common main path between transistors P6 and N5, while the gate of transistor N2, having a voltage V2 connects to the common main path between the transistors P8 and N7. The main path connection between transistors N1 and N2 intern connects to the main path of a transistor N9, which on the other hand connects to voltage line Vss. The drain of transistor N9 is interconnected with the drain of transistor N5. The gate of transistor P8 is interconnected with the drain of a transistor P10, the main path of which on the one hand connects to voltage supply line Vdd, and on the other hand provides a terminal with the desired reference current I_{ref}, alternatively denoted I_{DPB}. Also, the gate connection between transistors P8 and P6 connects with the main conduction path between the transistors P4 and N2.

In this circuit N1 and N2 together form a differential amplifier which via a first and a second main conduction path is connected in series with a second current mirror (P3, P4). A first current mirror (N5, N9) is connected to the main conduction path between the transistors of the differential pair by it's second main conduction path, while the first main conduction path connects to the first gate (N1) of the differential pair and, via transistor P6 via the second main conduction path of the differential pair and the gate of transistor P8 to the gate of transistor P10, providing the desired reference current in the main conduction path thereof.

The present invention thus also provides for a current source which can be used in all low voltage CMOS chips which require an on-chip current source for biasing analog subcircuits, by means of a transistor only circuit and in the form of a circuit requiring a relatively small chip area.

The present invention, apart from the preceding description and the various details of the pertaining figures, further relates to the subjects and features as defined in the following claims.

1. Integrated oscillator circuit of the relaxation type, characterized in that the circuit comprises a controllable current source I(β) and a gate oxide capacitor (Cox) which both have a dependency on a common transconductance β.

2. Integrated circuit according to claim 1, characterized in that the circuit comprises a first (I(β)2) and a second (I(β)2) current source controllable by respective switching means (Q1; Q2) and a gate oxide capacitor (Cox), all connected to the non-inverting input (+) of a differential amplifier means (D), the inverting input (−) of which differential amplifier connects to voltage input means (V1, V2) controllable via a switching means (QB1, QB2).

3. Integrated circuit according to claim 2, characterized in that the voltage input means comprises a pair of voltage reference sources (V1, V2), each source being connected to a voltage line (VSS) and being controllable by a switching means (QB1, QB2), the controlled output of each voltage reference being connected to the inverting input of the differential amplifier via a common connection.

4. Integrated oscillator circuit of the relaxation type, in particular according to any of the preceding claims, characterized in that the circuit comprises a controllable current source for generating a reference current (Iref) on the bases of a geometry difference of in the transistors (N1, N2) of a differential pair comprised in the circuit (N1-P10).

5. Integrated circuit according any of the preceding claims, characterized in that the reference curent circuit is solely composed of transistors.

6. Integrated circuit according to any of the preceding claims, characterized in that the current source comprises a differential pair (N1, N2) connected in series with a first current mirror (P3, P4), the main conductance path of which differential pair (N1, N2) is connected to a main conduction path (VSS, N9) of a second current mirror (N5, N9).

7. Integrated ciruit according to claim 6, characterized in that the main conduction path of the second current mirror (N5, N9) connects to the gate of one transistor (N1) of the differential pair, and to a transistor (P6), the gate of which connects to the gateof a further transistor (P10), the main path of which on the one side connects to a voltage line (VDD) and on the other side provides a terminal for a reference current.

8. Complementary metal oxide semi conductor comprising a circuit according to any of the preceding claims.
